(19) United States
(12) Patent Application Publication
(10) Pub. No.: US 2011/0247854 A1
(43) Pub. Date: Oct. 13, 2011

(54) MULTI-FILM STRUCTURE AND METHOD FOR MAKING SAME, AND ELECTRONIC DEVICE HAVING SAME

(75) Inventors: Ga-Lane CHEN, Santa Clara, CA (US); Chao-Tsang WEI, Tu-Cheng (TW); Chung-Pei WANG, Tu-Cheng (TW); Hsin-Chin HUNG, Tu-Cheng (TW)

(73) Assignee: HON HAI PRECISION INDUSTRY CO., LTD., Tu-Cheng (TW)

(21) Appl. No.: 12/857,566

(22) Filed: Aug. 17, 2010

(30) Foreign Application Priority Data
Apr. 9, 2010 (TW) 99111067

(51) Int. Cl. H05K 5/00

(52) U.S. Cl. 174/50

(57) ABSTRACT

A multi-film structure includes a substrate having a surface, a chromium nitride film formed on the surface of the substrate, and a color layer deposited on the chromium nitride film. The color layer includes an aluminum oxide film doped with chromium atoms. A weight percent of the chromium in the color layer is less than that of the aluminum in the color layer.

### BACKGROUND

1. Technical Field

The present disclosure relates to a multi-film structure, a method for making the multi-film structure, and an electronic device having the multi-film structure.

2. Description of Related Art

With the development of individuation of electronic devices, consumers have higher requirements for the appearance of the electronic devices. Therefore, besides the function, shape and color of the electronic devices are also important in attracting consumers. However, housings of the electronic devices are generally made of metal or plastic, the color of which is limited and tedious.

Therefore, it is desirable to provide a multi-film structure and a method for making the multi-film structure, which can overcome the above-mentioned limitations.

### BRIEF DESCRIPTION OF THE DRAWINGS

FIG. 1 is a cross-sectional view of a multi-film structure according to a first embodiment.

FIG. 2 is a schematic plan view of an electronic device according to a second embodiment.

FIG. 3 is a cross-sectional view of the electronic device of FIG. 2 taken along the line III-III.

FIG. 4 is a flow chart of a method for making the multi-film structure of FIG. 1.

FIG. 5 is a table showing coating parameters of a multi-film structure having a first color of milk tea and a testing result of the multi-film structure.

FIG. 6 is a table showing coating parameters of a purple multi-film structure and a testing result of the multi-film structure.

FIG. 7 is a table showing coating parameters of a multi-film structure having a second color of milk tea and a testing result of the multi-film structure.

FIG. 8 is a table showing coating parameters of a multi-film structure having a first color of blue and a testing result of the multi-film structure.

FIG. 9 is a table showing coating parameters of a red multi-film structure and a testing result of the multi-film structure.

FIG. 10 is a table showing coating parameters of a black multi-film structure and a testing result of the multi-film structure.

FIG. 11 is a table showing coating parameters of a multi-film structure having a second color of blue and a testing result of the multi-film structure.

FIG. 12 is a table showing coating parameters of a dark golden multi-film structure and a testing result of the multi-film structure.

FIG. 13 is a table showing coating parameters of an indigo multi-film structure and a testing result of the multi-film structure.

FIG. 14 is a table showing coating parameters of a yellow-green multi-film structure and a testing result of the multi-film structure.

### DETAILED DESCRIPTION

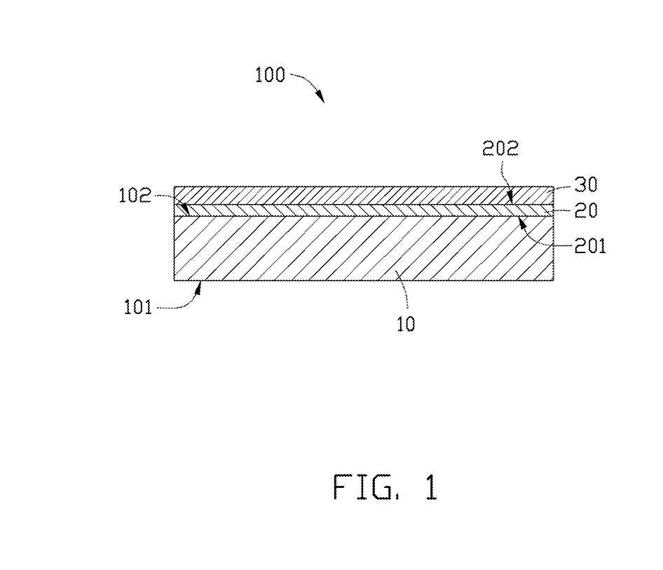

Referring to FIG. 1, a multi-film structure 100 according to a first embodiment is shown. The multi-film structure 100 includes a substrate 10, a chromium nitride film 20 formed on the substrate 10, and a color layer 30 formed on the chromium nitride film 20.

The substrate 10 may be a shell of a portable electronic device. The substrate 10 may be made of materials such as metal, or plastic. In the present embodiment, the substrate 10 is made of stainless steel. The substrate 10 includes a first bottom surface 101 and a first surface 102.

The chromium nitride film 20 is formed on the first surface 102 of the substrate 10. The chromium nitride film 20 includes a second bottom surface 201 and a second surface 202. The second bottom surface 201 is in contact with the first surface 102 of the substrate 10.

A molecular formula of the chromium nitride is represented by CrNx, and x is larger than 0 and less than 1. The chromium nitride film 20 is for enhancing the adhesion between the color layer 30 and the substrate 10.

The color layer 30 is formed on the second surface 202 of the chromium nitride film 20. The color layer 30 is an aluminum oxide film doped with chromium atoms. The weight percent of the chromium in the color layer 30 is less than that of the aluminum in the color layer 30. The multi-film structure 100 shows different colors depending on the weight percentage of the chromium in the color layer 30 and the thickness of the color layer 30. A molecular formula of the aluminum oxide film mixed with chromium atoms may be Al₂O₃:Cr.

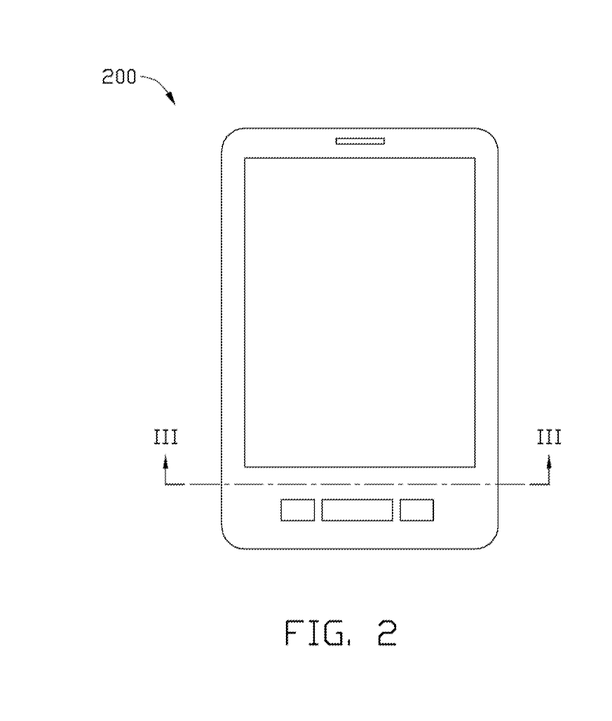

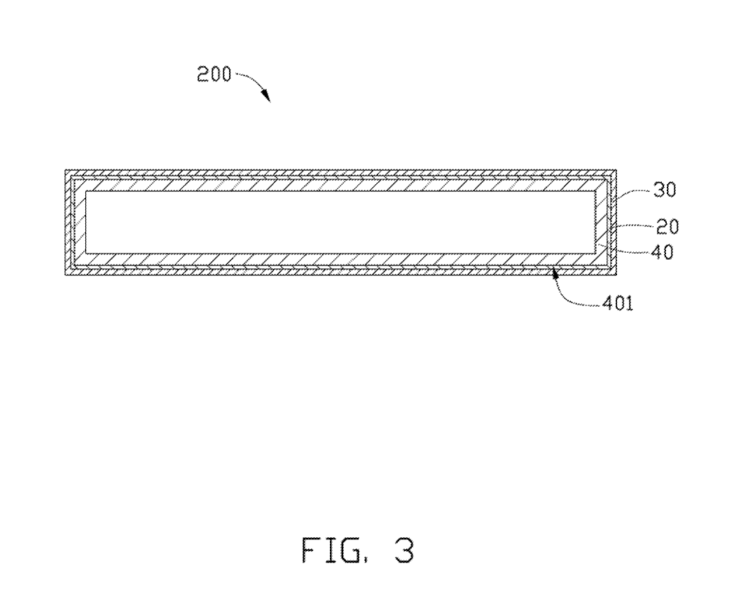

Referring to FIGS. 2-3, an electronic device 200 according to a second embodiment is shown. The electronic device 200 includes the multi-film structure 100 of FIG. 1. The electronic device 200 includes a housing 40 equivalent to the substrate 10 of FIG. 1. The housing 40 includes an exterior surface 401. The chromium nitride film 20 is formed on the exterior surface 401. In the present embodiment, the electronic device 200 is a cell phone.

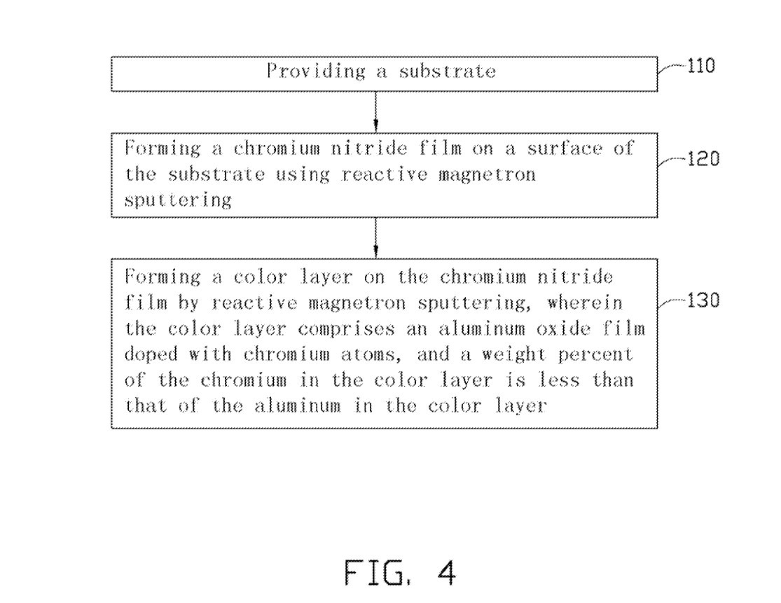

Referring to FIG. 4, a method for making the multi-film structure 100 includes the following steps:

In step 110, the substrate 10 is provided. The first surface 102 of the substrate 10 may be roughened, or smoothed.

In step 120, the chromium nitride film 20 is formed on the first surface 102 of the substrate 10 using reactive magnetron sputtering.

The reactive magnetron sputtering is performed in a reactive magnetron sputtering device (not shown). The reactive magnetron sputtering device includes a chamber. Before depositing the chromium nitride film 20, the substrate 10 is placed in the chamber, the chamber is then vacuumized and a working pressure of the chamber is kept at a stable value. In the present embodiment, the working pressure is about 4.1 millitorr.

Additionally, the chamber may be cooled using a condenser (not shown) during the process of vacuumizing to enhance the efficiency of vacuumizing. In this embodiment, a condensing temperature of the condenser is set to be about −135° C. After the chamber is vacuumized, the chamber may be heated to a required temperature.

Then, a chromium target is placed in the chamber, a first magnetic field and a first electrical field are applied between the chromium target (a first cathode) and the substrate (an anode), and a mixed gas of nitrogen and argon is continually introduced into the chamber during the coating of the chromium nitride film 20. The first magnetic field is orthogonal with the first electrical field. The nitrogen serves as reactive air, and the argon serves as working air. In the first electrical field, the argon is ionized to argon ions and electrons, argon ions are accelerated to strike on the chromium target, a number of chromium atoms escape from the chromium target, the chromium atoms react with the nitrogen to form chromium nitride. The chromium nitride is deposited on the first surface 102 of the substrate 10, thus forming the chromium nitride film 20.

In step 130, the color layer 30 is deposited on the second surface 202 of the chromium nitride film 20 using reactive magnetron sputtering.

After the chromium nitride film 20 is done, the chromium target is turned off, the mixed gas of nitrogen and argon is shut off, and the chamber is vacuumized. Before vacuumizing the chamber, the chamber may be cooled using a condenser (not shown). In the present embodiment, the condensing temperature of the condenser is set to be about −135° C. During the process of forming the color layer 30, a working pressure of the chamber is kept at a stable value.

Then, an aluminum target is placed in the chamber, a second magnetic field and a second electrical field are applied to the chromium target (the first cathode) and the substrate 10 (the anode), and a third magnetic field and a third electrical field are applied to the aluminum target (the second cathode) and the substrate 10 (the anode). The second magnetic field is orthogonal with the second electrical field, and the third magnetic field is orthogonal with the third electrical field. Subsequently, a mixed air of oxygen and argon is continually introduced to the chamber in the deposition of the color layer 30. The oxygen serves as reactive air, and the argon functions as working air. In the second and third electrical fields, the argon is again ionized to argon ions (with positive charge) and electrons. The argon ions are accelerated to strike to chromium target and the aluminum target, releasing a lot of chromium atoms and aluminum atoms. The aluminum atoms react with the oxygen to form aluminum oxide, and accordingly, the aluminum oxide film doped with chromium atoms is deposited on the second surface 202 of the chromium nitride film 20, thus forming the color layer 30.

In order to achieve that the weight percentage of aluminum atoms in the color layer 30 is greater than that of chromium in the color layer 30, power supplied to the aluminum target should be larger than that supplied to the chromium target. In one embodiment, the power fed to the aluminum target is about 30 kilowatt (KW), and the power supplied to the chromium target is about 0.4 KW.

The multi-film structure 100 shows different colors depending on the weight percent of the chromium and the thickness of the color layer 30. The weight percent of the chromium is mainly determined by the power supplied to the chromium target and the aluminum target. The thickness of the color layer 30 is mainly decided by the time of coating.

In the present embodiment, during the deposition of the chromium nitride film 20 and the color layer 30, the substrate 10 is driven to rotate around a central axis of the chamber, and simultaneously, to rotate around a central axis thereof so that uniformity of the chromium nitride film 20 and the color layer 30 is improved. A revolution speed (i.e., the speed of the rotation around the central axis of the chamber) of the substrate 10 is about 2 revolution per minute (RPM), and a rotation speed (i.e., the speed of the rotation around the central axis around the substrate 10) of the substrate is about 8 RPM.

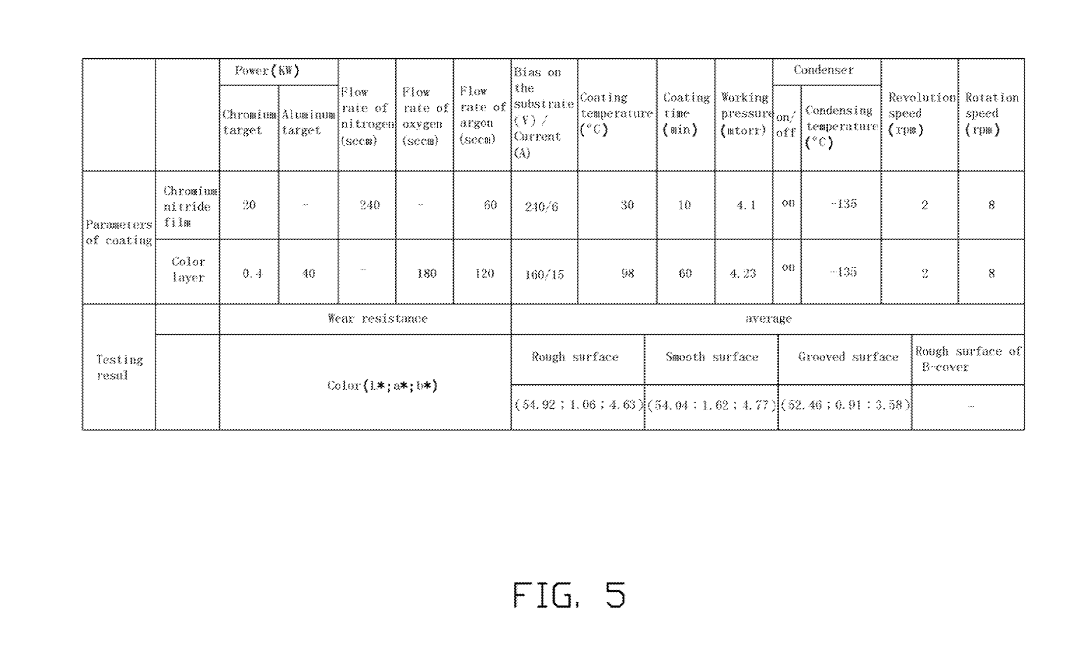

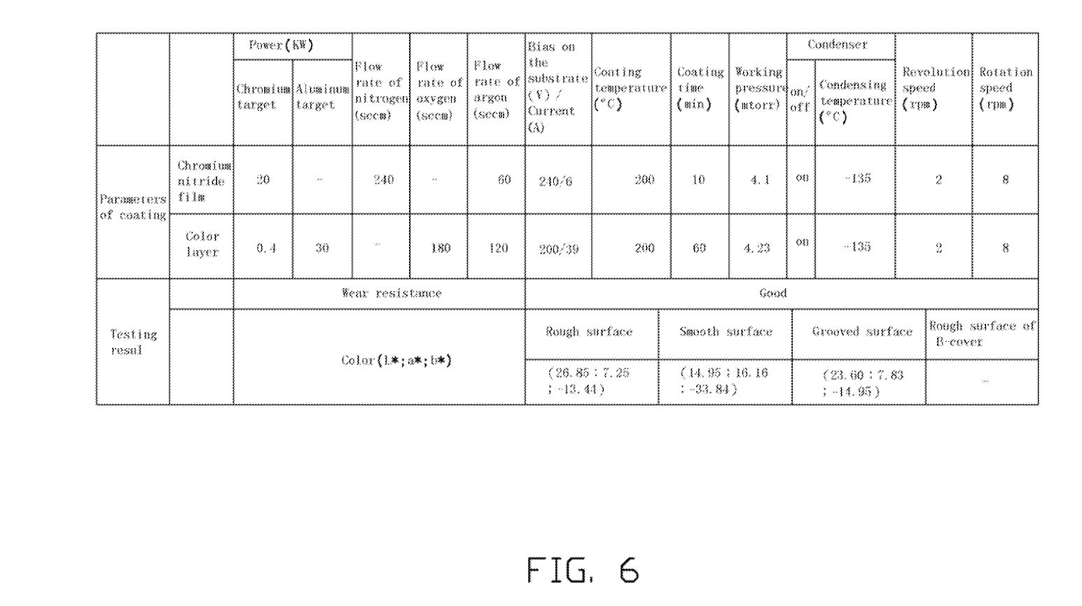

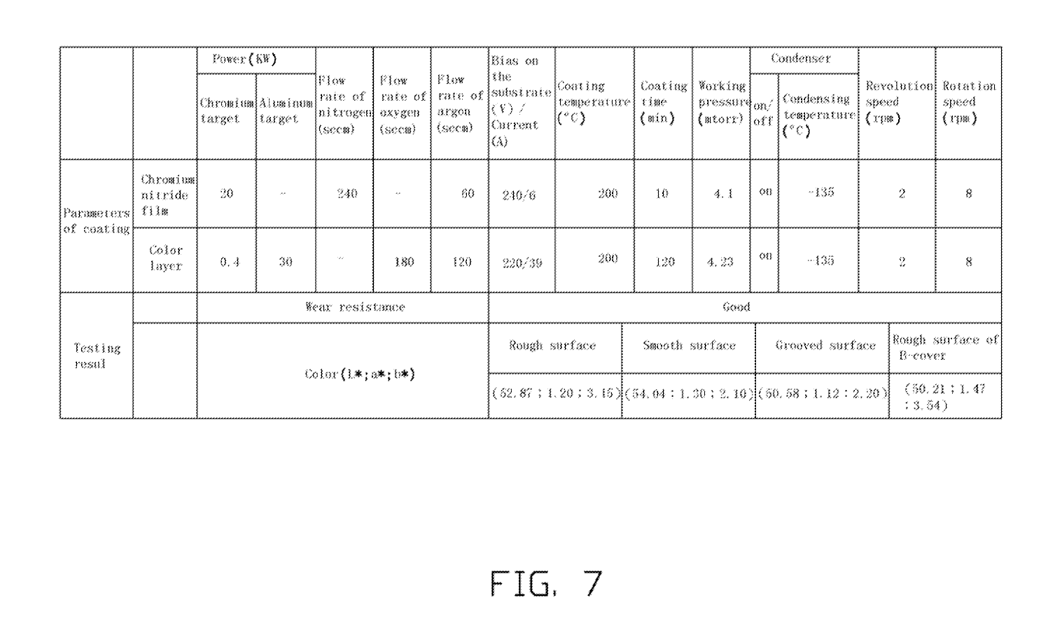

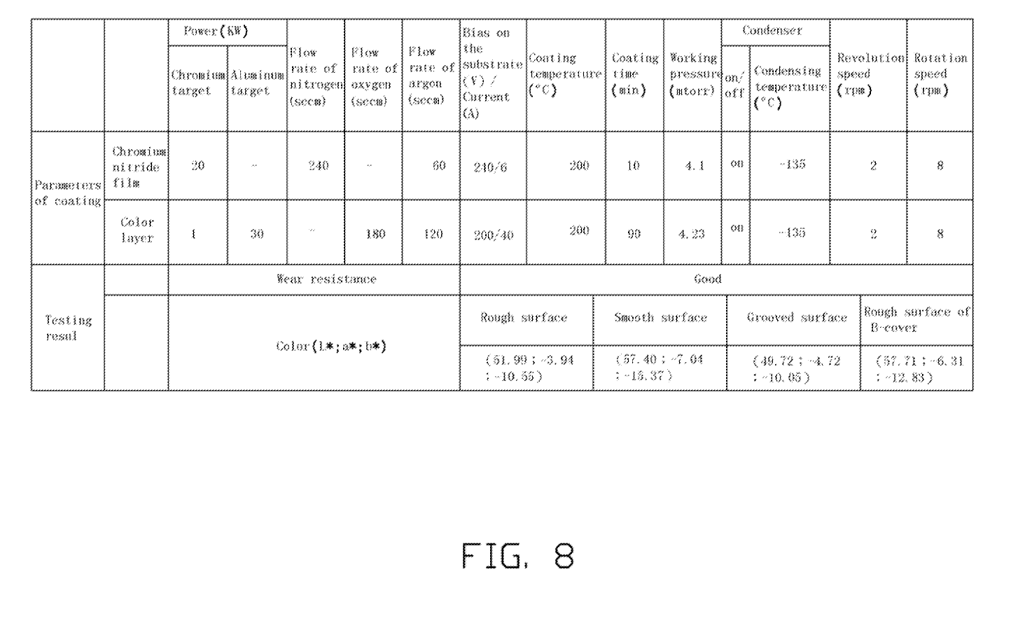

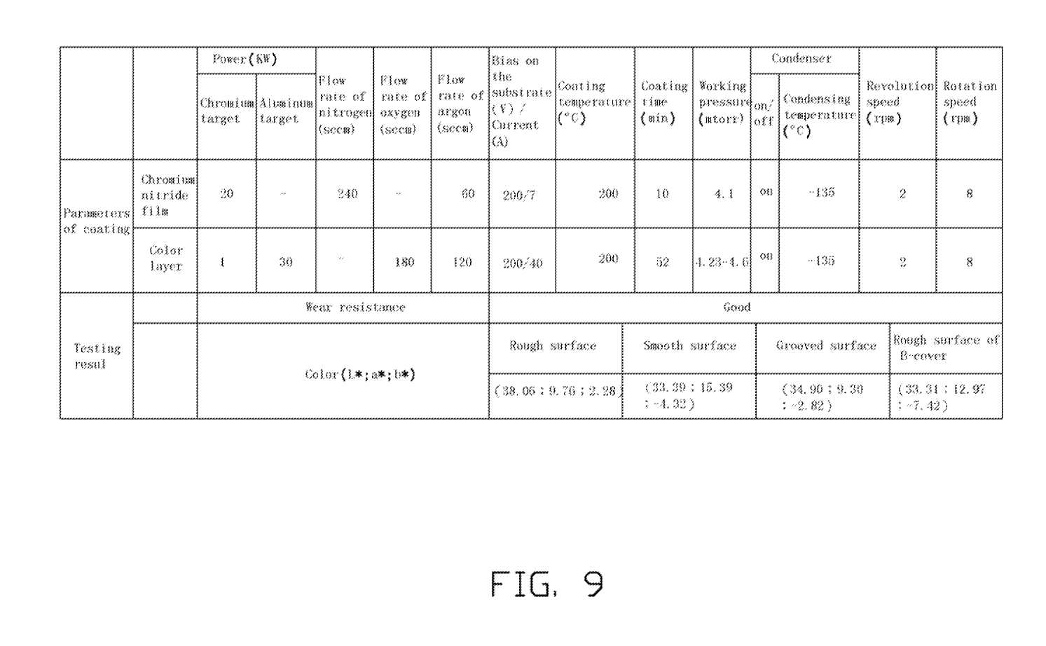

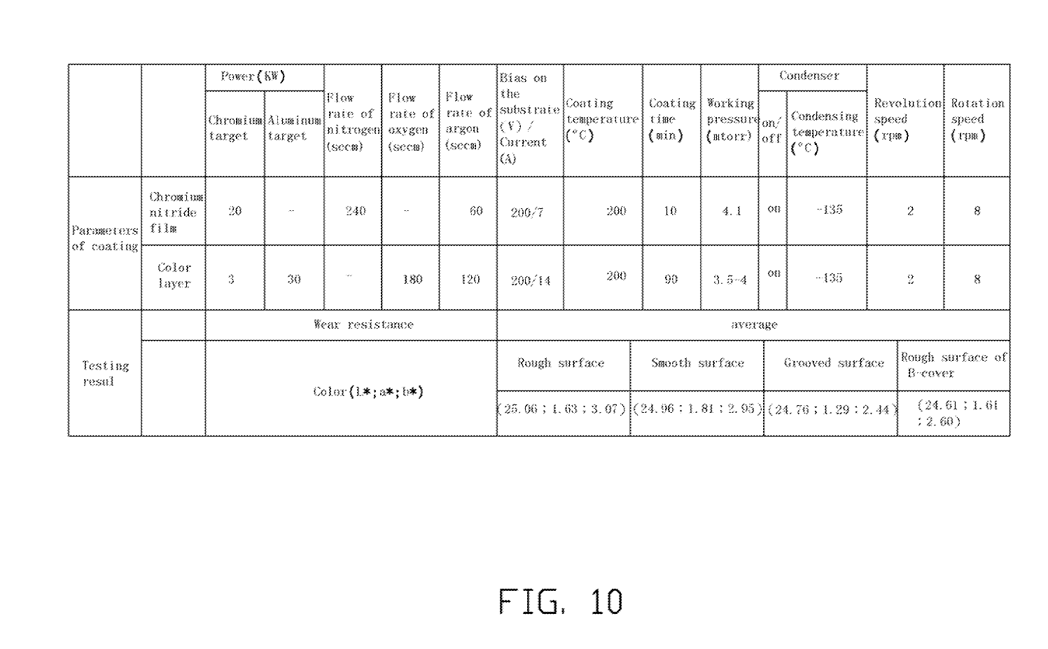

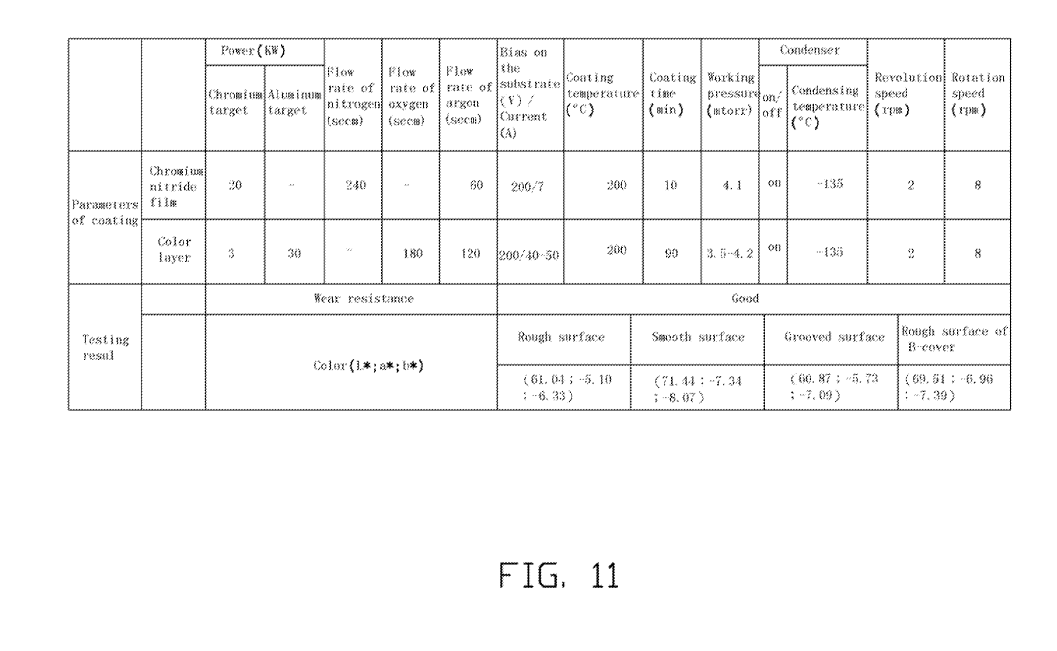

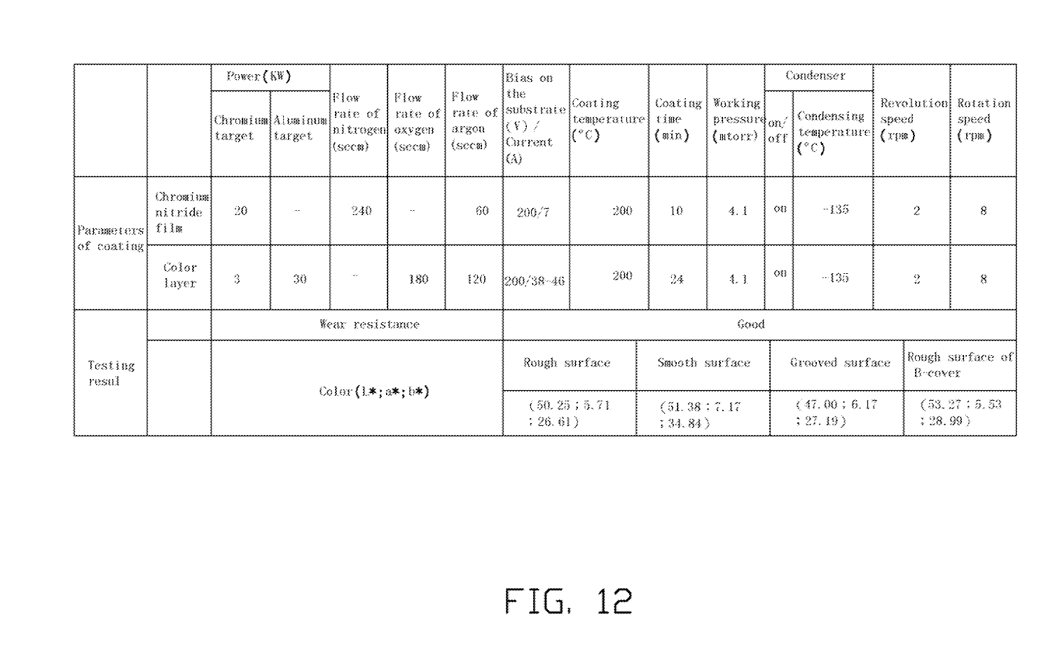

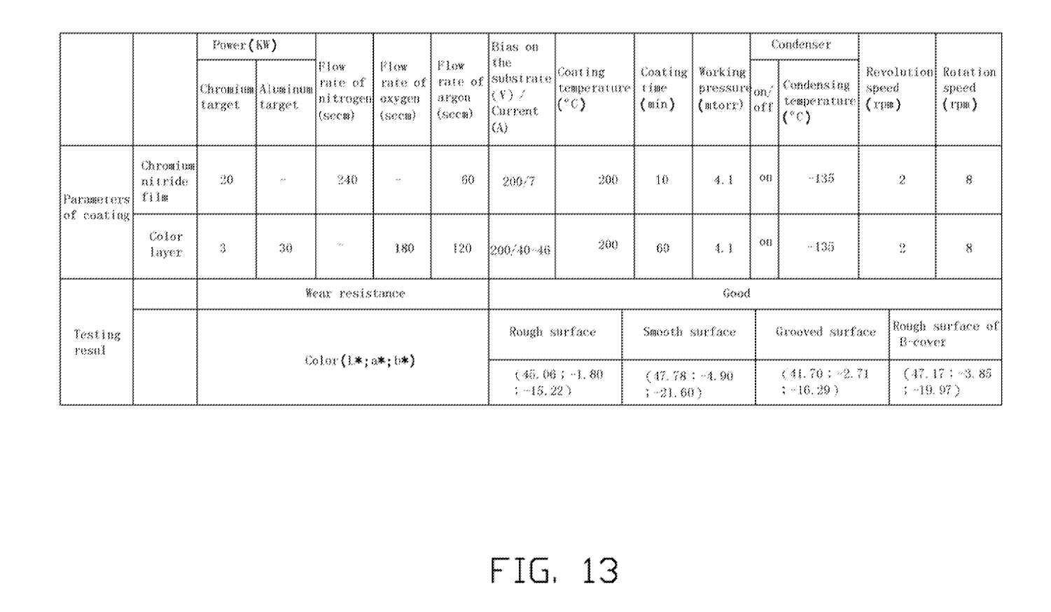

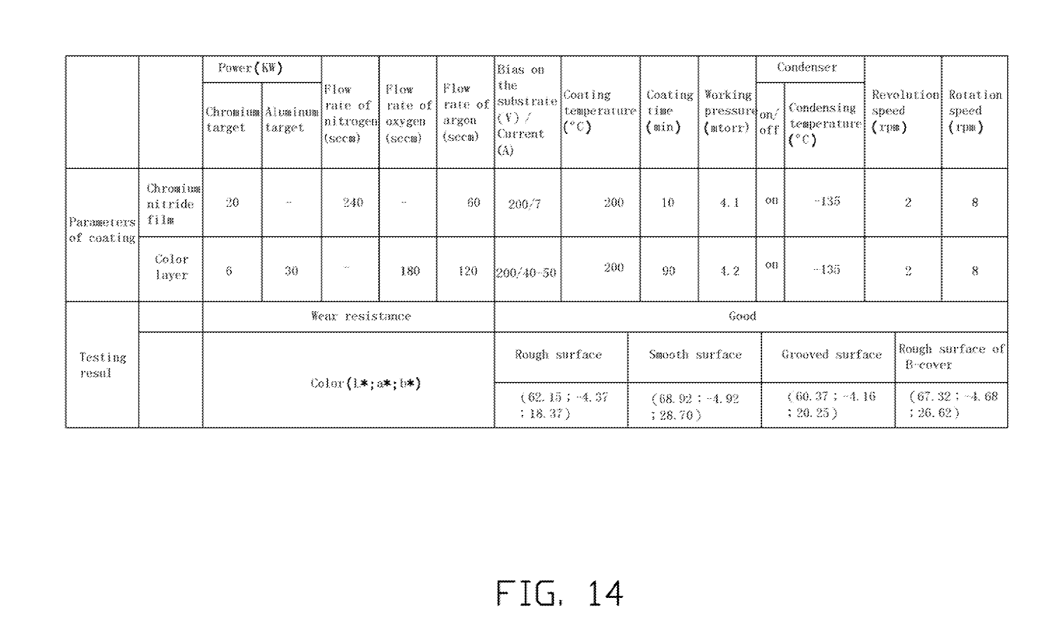

Referring to FIGS. 4-14, ten multi-film structures 100 are obtained using the above method under different coating parameters. The ten multi-film structures 100 have different colors and different wear resistance. In FIGS. 4-14, a unit of a flow rate of different gases (e.g, argon) is standard cubic centimeter per minute (sccm).

While various embodiments have been described, it is to be understood that the disclosure is not limited thereto. To the contrary, various modifications and similar arrangements (as would be apparent to those skilled in the art), are also intended to be covered. Therefore, the scope of the appended claims should be accorded the broadest interpretation so as to encompass all such modifications and similar arrangements.

What is claimed is:

1. A multi-film structure, comprising:
a substrate having a surface;
a chromium nitride film formed on the surface of the substrate; and
a color layer formed on the chromium nitride film, the color layer comprising aluminum oxide doped with chromium, wherein a weight percent of the chromium in the color layer is less than that of the aluminum in the color layer.

2. The multi-film structure of claim 1, wherein a molecular formula of the chromium nitride is represented by CrNx, and x is larger than 0 and less than 1.

3. The multi-film structure of claim 1, wherein the surface is one of a smooth surface, a rough surface, and a grooved surface.

4. The multi-film structure of claim 1, wherein the chromium nitride film is in contact with the substrate.

5. The multi-film structure of claim 1, wherein the color layer contacts the chromium nitride film.

6. The multi-film structure of claim 1, wherein the substrate is made of stainless steel.

7. A method for forming a multi-film structure, comprising:
forming a chromium nitride film on a surface of a substrate using a reactive magnetron sputtering process; and
forming a color layer on the chromium nitride film using a reactive magnetron sputtering process, wherein the color layer comprises aluminum oxide doped with chromium, and a weight percent of the chromium in the color layer is less than that of the aluminum in the color layer.

8. The method of claim 7, further comprising roughening and smoothening the surface of the substrate prior to forming the chromium nitride film.

9. The method of claim 7, further comprising steps of placing the substrate in a chamber, and vacuumizing the chamber, prior to forming the chromium nitride film.

10. The method of claim 9, wherein a working pressure of the chamber is kept at about 4.1 millitorr during forming the chromium nitride film.

11. The method of claim 9, wherein in the step of vacuumizing the chamber, the chamber is cooled using a condenser, a condensing temperature of the condenser is about −135° C.

12. The method of claim 9, further comprising a step of heating the chamber after vacuumizing the chamber and prior to forming the chromium nitride film.

13. The method of claim 7, further comprising the steps of: placing a chromium target and a substrate in the chamber, applying a magnetic field and an electrical field between the chromium target and the substrate, and introducing a mixed gas of argon and nitrogen, prior to forming the chromium nitride film.

14. The method of claim 9, further comprising vacuumizing the chamber prior to forming the color layer.

15. The method of claim 14, wherein a working pressure of the chamber is kept at about 4.1 millitorr during forming the color layer.

16. The method of claim 14, wherein the chamber is cooled using a condenser during the step of vacuumizing, and the condensing temperature is about −135° C.

17. The method of claim 14, further comprising a step of heating the chamber after vacuumizing the chamber.

18. The method of claim 9, wherein after forming the chromium nitride film and before forming the color layer, the method further comprises: placing a chromium target and an aluminum target in the chamber, applying a magnetic field and an electrical field between the substrate and the chromium target, applying a magnetic field and an electrical field between the substrate and the aluminum target, and introducing a mixed gas of oxygen and argon.

19. The method of claim 18, wherein a sputtering power of the aluminum target is greater than that of the chromium target.

20. An electronic device comprising:
a housing having an exterior surface;
a chromium nitride film formed on the exterior surface; and
a color layer formed over the chromium nitride film, the color layer comprising aluminum oxide doped with chromium, wherein a weight percent of the chromium in the color layer is less than that of the aluminum in the color layer.
